(19) United States
(12) Patent Application Publication
(10) Pub. No.: US 2023/0332330 A1
(43) Pub. Date: Oct. 19, 2023

(54) DEVICE FOR GROWING SINGLE CRYSTALS, IN PARTICULAR SINGLE CRYSTALS OF SILICON CARBIDE

(71) Applicant: EBNER Industrieofenbau GmbH, Leonding (AT)

(72) Inventors: Robert EBNER, Leonding (AT); Kanaparin ARIYAWONG, Leonding (AT); Ghassan BARBAR, Neunkirchen (DE); Chih-Yung HSIUNG, Leonding (AT)

(73) Assignee: EBNER Industrieofenbau GmbH, Leonding (AT)

(21) Appl. No.: 18/028,674

(22) PCT Filed: Sep. 23, 2021
(86) PCT No.: PCT/AT2021/060339

§ 371 Date: Mar. 27, 2023

(30) Foreign Application Priority Data
Sep. 28, 2020 (AT) A 50817/2020

(51) Int. Cl. C30B 35/00; C30B 29/36

(52) U.S. Cl. CPC C30B 35/002; C30B 29/36

(57) ABSTRACT

A device for growing single crystals, in particular single crystals of silicon carbide, includes a crucible, which crucible defines an outer lateral surface and moreover delimits an accommodation space with an axial extension between a bottom section and an opening section, wherein the accommodation space is designed for growing the crystals, wherein the device hast at least one seed crystal layer wherein the crucible is arranged in a chamber, in particular made of a glass material, for example quartz glass, wherein an induction heater is arranged around the chamber. The crucible is designed to have multiple parts and includes a crucible bottom section, at least one crucible wall part, and a crucible cover part, which are releasably connected to one another.

The invention relates to a device for growing single crystals, in particular single crystals of silicon carbide, comprising a crucible, which crucible defines an outer lateral surface and moreover delimits an accommodation space with an axial extension between a bottom section and an opening section, wherein the accommodation space is designed for growing the crystals, wherein the device has at least one seed crystal layer, wherein the crucible is arranged in a chamber, in particular made of a glass material, for example quartz glass, wherein an induction heater is arranged around the chamber.

For many technical applications, single crystals are nowadays produced on an industrial scale. Based on the phase transitions leading to the crystal, a distinction can be made between the growth from the melt, from the solution and from the gas phase. In the case of growth from the gas phase, further distinctions can be made between the production methods of the sublimation and/or the physical vapor deposition and the method of the chemical vapor deposition. In the case of the physical vapor deposition, the substance to be grown is vaporized by means of heating, so that it transitions into the gas phase. Given suitable conditions, the gas can re-sublimate on a seed crystal, whereby a growth of the crystal takes place. The raw material (powder or granules) usually present in a polycrystalline form is thus recrystallized. The chemical vapor deposition works in a similar manner. In this process, the transition of the substance to be grown into the gas phase is only possible by means of an auxiliary substance, to which the substance chemically binds itself, since the vapor pressure would be too low otherwise. Thus, a higher transport rate towards the seed crystal is achieved in combination with the auxiliary substance.

A great interest is taken in silicon carbide single crystals, particularly because of their semiconductor properties. Their production is carried out in furnaces with a crucible, in which the silicon carbide raw material is heated, and a seed crystal, on which the further crystal growth takes place by means of accumulation. Moreover, the interior of the process chamber is evacuated. The material used for the innermost process chamber with the crucible is graphite. Usually, the seed crystal is located directly on a cover of a crucible containing the raw material.

A problem, which arises in the known solutions, is that depending on the size to be produced of a silicon carbide single crystal and the respective furnace size, different crucibles are used. Furthermore, the handling of larger crucibles may prove difficult both during process preparation and when removing the finished single crystal.

Hence, it is the object of the invention to overcome the disadvantages of the prior art and to allow for a quick adaptation of a crucible to different process conditions and to simplify the handling.

This object is achieved according to the invention with a device of the initially mentioned type by the crucible being designed to have multiple parts and comprising a crucible bottom part, at least one crucible wall part and a crucible cover part, which are releasable connected to one another.

With the solution according to the invention a kind of modular design is formed in order to be able to adapt the crucible dimensions to what is required for each process.

According to an advantageous variant of the invention, it may be provided that a positioning assembly is provided, by means of which positioning assembly at least the crucible bottom part and the at least one crucible wall part are positioned on the ends facing one another oriented in a predefined position relative to one another.

An optimal yield of the base material can be achieved in that the device has a guide surface running towards the seed crystal layer and inclined against an axis of the accommodation space, wherein the shortest distance from the guide surface to the axis of the accommodation space decreases from a lower edge of the guide surface facing the bottom section towards an upper edge of the guide surface facing a cover of the crucible.

It has proven particularly advantageous that the guide surface is designed conically.

In order to realize a modular design, it has proven very favorable that the guide surface is part of an insert inserted into the crucible, wherein the insert and/or the crucible bottom part and/or the crucible wall part and/or the crucible cover part is preferably made of ceramics, of metal, or a mineral material, in particular molybdenum, graphite, SiC, or Al₂O₃.

According to an advantageous advancement of the invention, which allows for an easy positioning of the insert in the crucible, it may be provided that the insert comprises a holding projection protruding from the guide surface in the radial direction and facing a side wall of the accommodation space.

According to an advantageous variant, it may be provided that the holding projection is designed to extend around the guide surface in the circumferential direction.

It is particularly preferred that the holding projection is arranged, at least in sections, between the crucible bottom part and the crucible wall part or between two sections of the crucible wall part.

In a very advantageous variant, which also enables easy filling of the crucible with the base material, it may be provided that the crucible bottom part is designed to be pot-shaped, and the crucible wall part is designed to be tubular, wherein the crucible bottom part and the crucible wall part are arranged on top of one another so as to be aligned with one another.

In order to make a targeted process control possible, the device may comprise a pyrometer for detecting at least a temperature of the crucible or in the crucible.

In this regard, it has proven particularly advantageous that the crucible cover part has an opening, wherein the device is configured to detect, through said opening, a temperature in the accommodation space or on a side of the seed crystal layer facing away from the accommodation space by means of the pyrometer.

For the purpose of better understanding of the invention, it will be elucidated in more detail by means of the figures below.

These show in a respectively very simplified schematic representation:

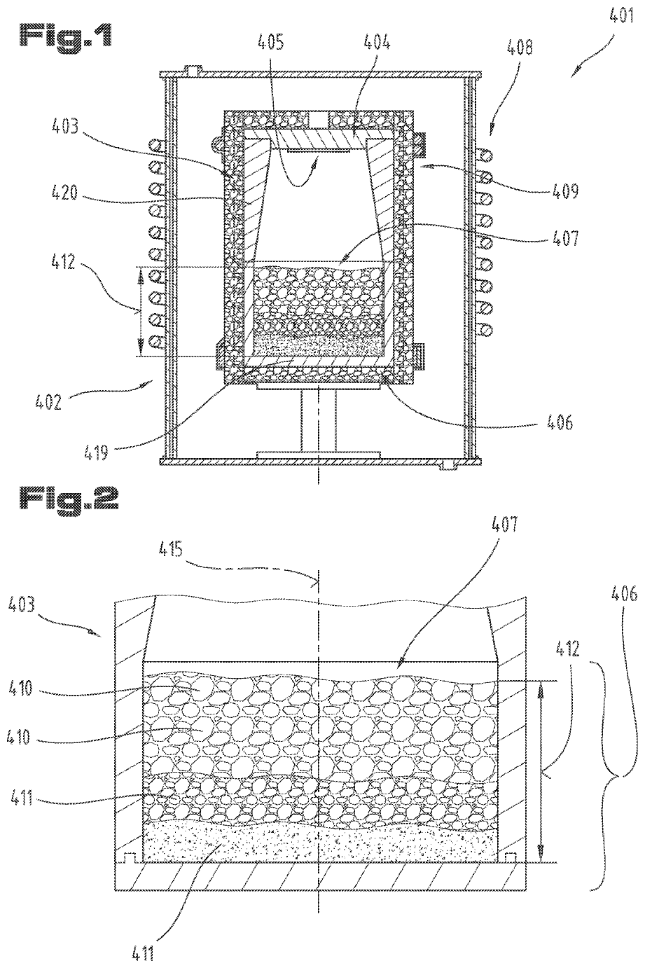

FIG. 1 a device for producing single crystals by means of physical vapor deposition;

FIG. 2 a detail of the crucible of the device according to FIG. 1;

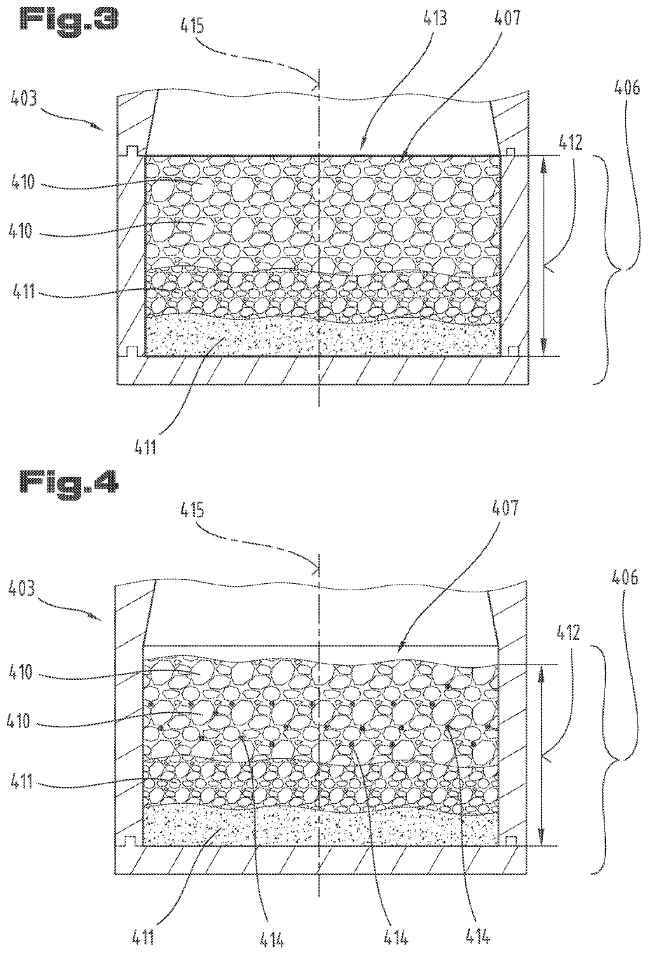

FIG. 3 a second exemplary embodiment of the device for single crystal production, with a base material formed into a pellet;

FIG. 4 a third exemplary embodiment of the device for single crystal production;

FIG. 5 a fourth exemplary embodiment of the device for single crystal production;

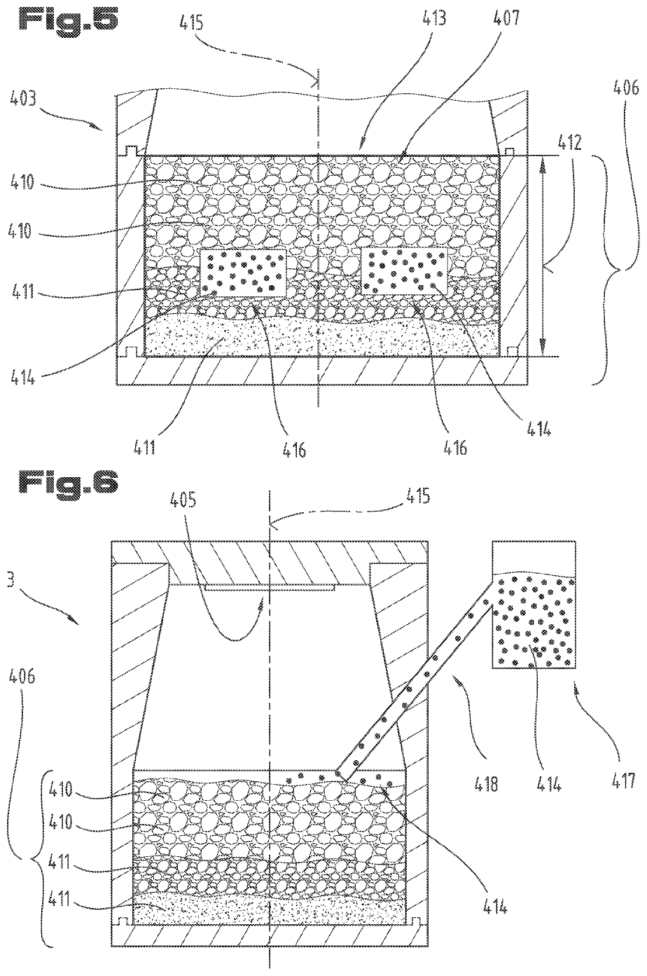

FIG. 6 a fifth exemplary embodiment of the device for single crystal production;

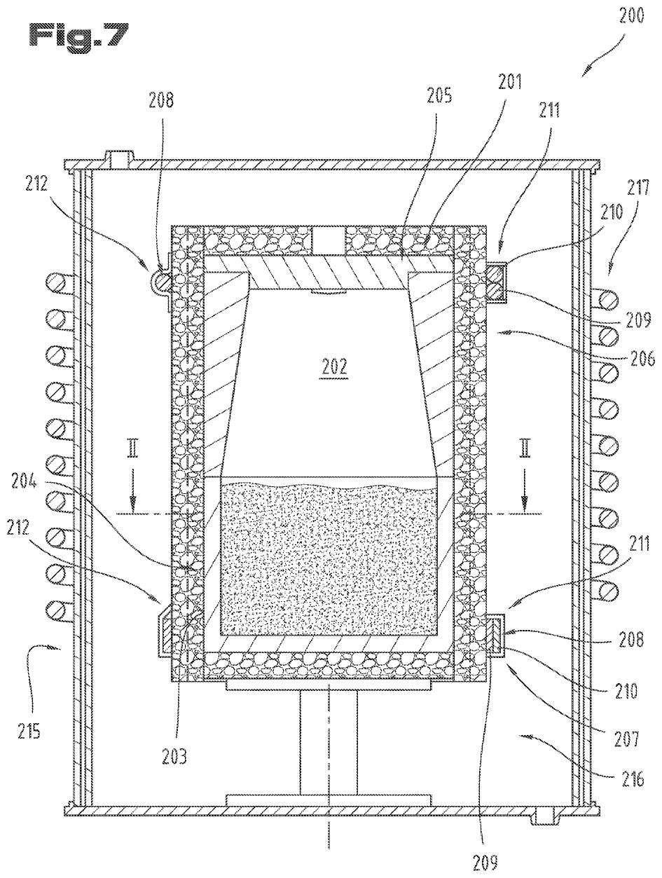

FIG. 7 an exemplary embodiment of a device for crystal formation with a crucible, on the outside of which an enveloping unit is held positioned by means of a holding unit thereon, in an axial section;

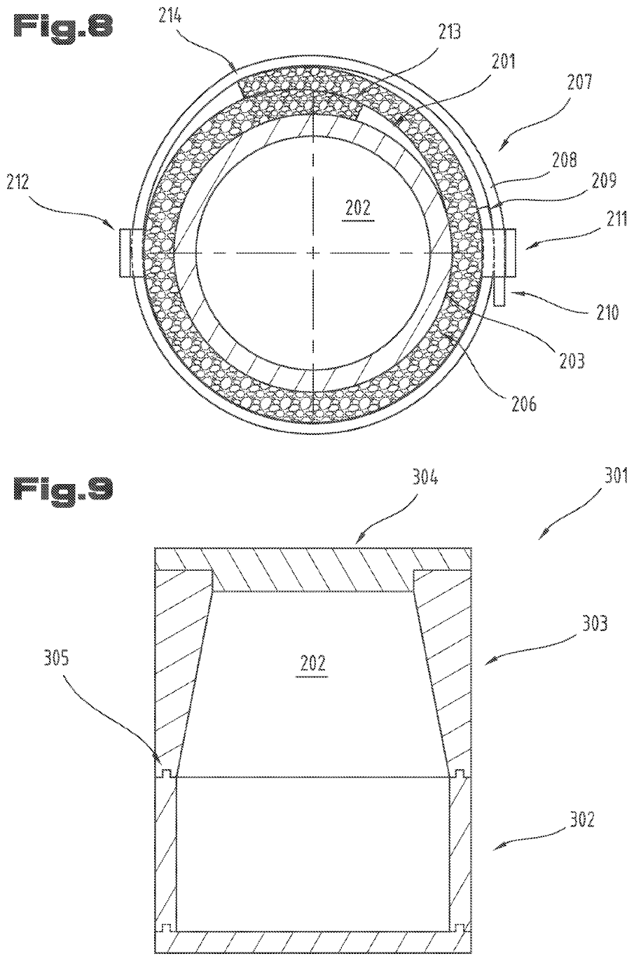

FIG. 8 the crucible according to FIG. 7, including its enveloping unit and holding unit alone, in a cross section according to lines II-II in FIG. 1;

FIG. 9 a further possible embodiment of a crucible, in an axial section;

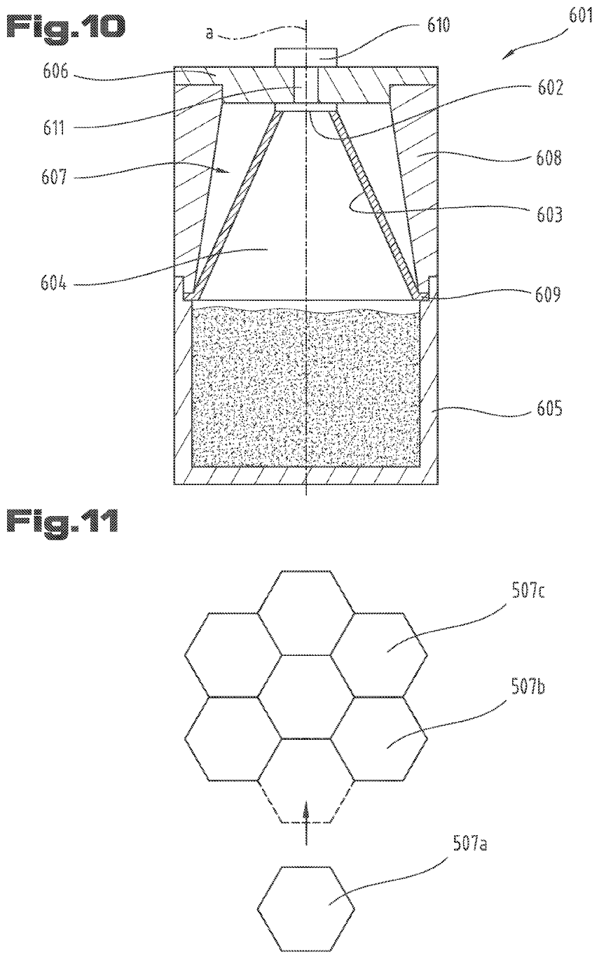

FIG. 10 a further possible embodiment of a crucible;

FIG. 11 a seed crystal layer;

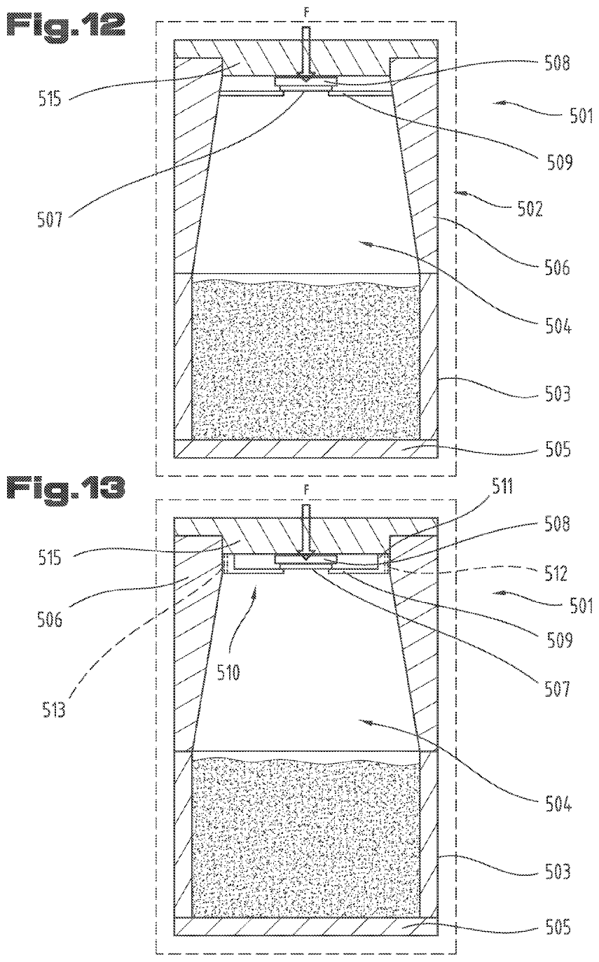

FIG. 12 a further embodiment of a crucible;

FIG. 13 a further variant of a crucible;

FIG. 14 a further variant of a crucible, and

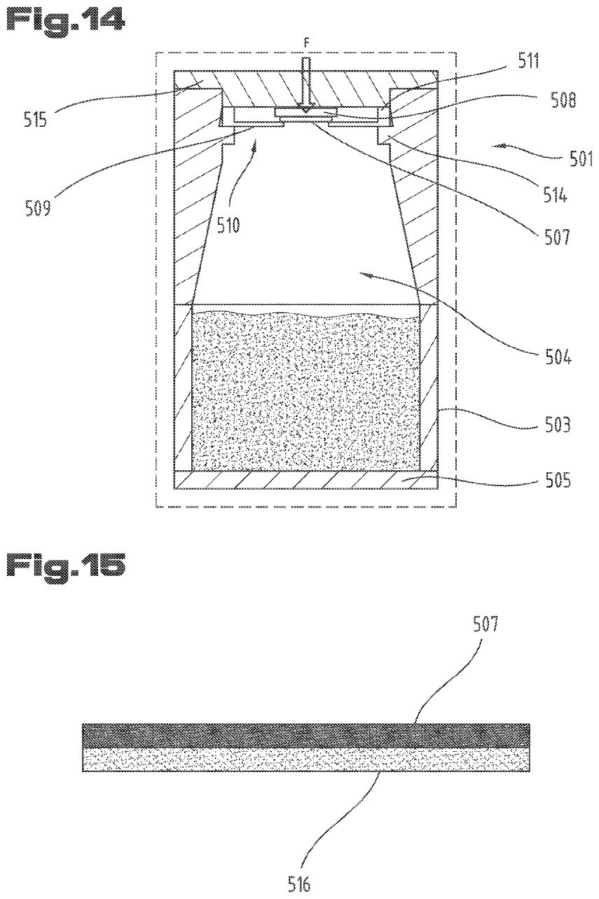

FIG. 15 a section through a substrate and a seed crystal layer arranged thereon.

First of all, it is to be noted that in the different embodiments described, equal parts are provided with equal reference numbers and/or equal component designations, where the disclosures contained in the entire description may be analogously transferred to equal parts with equal reference numbers and/or equal component designations. Moreover, the specifications of location, such as at the top, at the bottom, at the side, chosen in the description refer to the directly described and depicted figure and in case of a change of position, these specifications of location are to be analogously transferred to the new position.

FIG. 1 shows a device 401 in the form of a furnace for producing single crystals by means of physical vapor deposition. The furnace comprises a chamber 402, which can be evacuated, with a crucible 403 accommodated therein. The crucible 403 is designed to be essentially pot-shaped, wherein an upper end region is closed by a cover 404. A bottom side of the cover 404 of the crucible 403 is, in this regard, usually configured to fasten a seed crystal 405. In a bottom region 406 of the crucible 403, a base material 407 is present, which serves as a raw material for the crystal growth on the seed crystal 405, and which is gradually consumed during the production process.

The transition of the base material 407 into the gas phase is achieved by heating with the aid of a heater 408. According to this exemplary embodiment, the heating of the base material 407 and the crucible 403 by means of the heater 408 is carried out inductively. The crucible 403 arranged in the chamber 402 is moreover enveloped by an insulation 409 for thermal insulation. By means of the insulation 409, thermal losses from the crucible 403 are simultaneously prevented, and a heat distribution favorable for the growth process of the crystal on the seed crystal 405 is achieved in the interior of the crucible 403.

The material for the chamber 402 is preferably a glass material, in particular a quartz glass. The crucible 403 and the insulation 409 surrounding it preferably consist of graphite, wherein the insulation 409 is formed by a graphite felt.

Because atoms and/or molecules of the base material 407 transition into the gas phase due to heating of the base material 407, the atoms and/or molecules can diffuse to the seed crystal 405 in the interior of the crucible 403 and accumulate thereon, whereby the crystal growth takes place.

In this process, the formation of a single crystal being as free of impurities as possible is aimed for. The quality of the crystal forming on the seed crystal 405 depends on the temperature gradient between the base material 407 and the seed crystal 405 as well as on the vaporization rate of the base material 407. The latter, in turn, depends on the form in which the raw material of the base material 407 is provided in the crucible 403. In this regard, it proves advantageous if the base material 407 is formed by a mixture of a powdery raw material and a raw material present in the form of lumps.

The crucible 403 is designed to have multiple parts and comprises a crucible bottom part 419, a crucible wall part 420, and a crucible cover part in the form of the cover 404, which are releasably connected to one another.

FIG. 2 shows a detail of the crucible 403 of the furnace 401 according to FIG. 1. In this exemplary embodiment, silicon carbide is provided as the raw material for the base material 407. In this regard, the silicon carbide of the base material 407 comprises both lumps 410 and powder 411. The lumps 410 and the powder 411 of the silicon carbide are, in this regard, loosely layered in the bottom section 406 of the crucible 403. As adumbrated in the image according to FIG. 2, the powder 411 and the lumps 410 are present as a mixture. It proves advantageous here, if in different height ranges of the bottom section 406, the base material 407 is present in different mix ratios of lumps 410 and powder 411.

The duration of a production process of a single crystal of silicon carbide in the furnace 401 usually stretches over multiple days. In this regard, the consumption of the raw material of the base material 407 also depends on the temperature distribution created in the base material 407 by the heater 408, wherein the vaporization rate of the raw material may change accordingly over the duration of the process. This is because a gradual compacting due to superficial melting of the particles of the initially loosely distributed raw material of the base material 407 ensues. A different mix ratio of silicon carbide lumps 410 and silicon carbide powder 411 in the different filling regions and/or in the different height ranges of the bottom section 406 filled therewith may contribute to a vaporization rate that is as steady as possible during the correspondingly long duration of the entire crystallization process. The mix ratio of lumps 410 and powder 411 is significant insofar as powder 411 of the raw material is synonymous with a large surface and thus a great vaporization rate, and at the same time, lumps 410 having a smaller surface in total result in a lower vaporization rate.

In the exemplary embodiment according to FIG. 2, lumps 410 and powder 411 are layered up to a height 412 with different mix ratios. In this regard, the silicon carbide powder 411 is contained in a first, lower third of the height 412 of the base material 407 with a proportion of 55% to 70% of the weight. Correspondingly complementary to this, silicon carbide lumps 410 are contained in the lower third of the height 412 with a proportion of 30% to 45%. In a second, middle third of the height 412 of the base material 407, powder 411 is contained with a proportion of 40 wt. % to 55 wt. % and, with a correspondingly complementary proportion, lumps 410 are contained with 45 wt. % to 60 wt. %. In a third, upper third of the height 412 of the base material 407, finally, silicon carbide powder 411 is contained with a proportion of 25% to 40% and complementary to this, silicon carbide lumps 410 are contained with 60% to 75%.

The silicon carbide powder 411 has a grain size with a value from a range between 150 μm and 1000 μm. The silicon carbide lumps 410 have a grain size with a value from a range between 1 mm and 5 mm. In this regard, it is further provided that the silicon carbide is used having a great purity. For both the silicon carbide lumps 410 and the powder 411, a material purity of greater than 5 N is provided.

Based on the total mass of the overall base material 407 filled into the bottom region 406 of the crucible 403 at the beginning of the process, a mix ratio of silicon carbide powder 411 and silicon carbide lumps 410 is provided with 40 wt. % silicon carbide powder 411 to 60 wt. % silicon carbide lumps 410. However, mix ratios in a variation range of 25 wt. % silicon carbide powder 411 to 75 wt. % silicon carbide lumps 410 up to 55 wt. % silicon carbide powder 411 to 45 wt. % silicon carbide lumps 410 are also suitable.

FIG. 3 shows a second exemplary embodiment of the device for producing single crystals according to FIG. 1. In it, again, only a detail of the crucible 403 with the bottom section 406 is shown. The base material 407 of the mixture of the silicon carbide, which is filled into the bottom region 406 of the crucible 403, is formed by a pellet 413 in this case. The base material 407 of said pellet 413 also consists of a mixture of silicon carbide powder 411 and silicon carbide lumps 410. Just like in the exemplary embodiment according to FIG. 2, a variable distribution of the mix ratio of lumps 410 and powder 411 over the progression of the height 412 is provided. In order to produce a pellet 413, the silicon carbide lumps 410 and the silicon carbide powder 411 are pressed into a compact body in a preceding production process. It is also possible to carry out a heat treatment (a sintering process) of the silicon carbide mixture of the base material 407 to produce the pellet 413.

FIG. 4 shows a third exemplary embodiment of the device for producing single crystals according to FIG. 1. In this regard, the mixture of silicon carbide lumps 410 and silicon carbide powder 411 of the base material 407 additionally contains elementary silicon 414. Said silicon 414 is preferably mixed into the base material 407 in the form of fine-grained granules and/or as a powder, and also has a great material purity. The elementary silicon 414 preferably has a material purity of greater than 5 N. By adding the silicon 414 to the base material 407, a silicon deficiency developing in the silicon carbide mixture of the base material 407 over the duration of the crystallization process can be balanced out and/or compensated. In this exemplary embodiment, the elementary silicon 414 constitutes a weight proportion of the total mass of the base material 407 with a value from a range between 5 wt. % and 50 wt. %. This is preferably mixed into the base material 407 in the second, middle third and in the third, upper third of its height 412.

FIG. 5 shows a fourth exemplary embodiment of the furnace 401 with the crucible 403. The accommodation space of the crucible 403 in its bottom section 406 forms a volume, which is essentially rotationally symmetrical about an axis 415 and/or cylindrical. The base material 407 is moreover formed by a pellet 413 made of lumps 410 and powder 411 of silicon carbide. Additionally, stores 416 and/or reservoirs with elementary silicon 414 are formed into and/or enclosed in the volume of the pellet 413. The stores 416 in the pellet 413 preferably contain powdery silicon 414. The quantity of the silicon 414 added to the pellet 413 is preferably enclosed in the same in the form of an annularly connected store 416. The volume of the silicon 414 may be stored in the pellet 413 of the base material 407 for example in the form of a ring and/or a torus.

FIG. 6 shows a further, alternative exemplary embodiment of the device for producing single crystals of silicon carbide. In this regard, the image of the furnace 401 only shows its crucible 403 and additionally a storage container 417 for powdery and/or granular silicon 414. In the same way already described with the aid of FIG. 2, the base material 407 is initially formed by a mixture of lumps 410 and powder 411 of the silicon carbide in this exemplary embodiment, as well, and this mixture is loosely poured and/or layered in the bottom section 406 of the crucible 403. Due to the arrangement of the storage container 417 with the elementary silicon 414, it is possible to supply elementary silicon 414 in addition to the silicon carbide to the base material 407 in different phases during the course of the crystallization process. For this purpose, a feed line 418 is provided between the storage container 417 arranged outside the crucible 403 and the interior of the crucible 403, by means of which feed line 418 the silicon 414 is conveyed. This may take place, for example, by means of a screw conveyor (not shown), which feeds the silicon 414 to the line 418 and/or conveys the silicon 414 through it.

FIGS. 7 and 8 show a possible exemplary embodiment of a device 200 in different views, which device 200 serves to grow crystals or is configured therefor.

For this purpose, a crucible 201, among other things, is provided, which delimits an accommodation space 202 in its interior in a known manner. In most cases, the crucible 201 has a hollow-cylindrical cross-section, wherein cross-sectional shapes deviating therefrom, such as polygonal, oval or the like, are also possible. The crucible 201 moreover defines an outer lateral surface 203. The accommodation space 202 has an axial extension in the direction of its height, which extends between a bottom section 204 and an opening section 205. The crucible 201 with its accommodation space 202 is configured to grow crystals.

Furthermore, an enveloping unit 206 is provided for thermally insulating and providing insulation for the crucible 201, which enveloping unit 206 covers the outer lateral surface 203 of the crucible 201 at least in sections but preferably completely. The enveloping unit 206 surrounds the crucible 201 completely in the circumferential direction in this exemplary embodiment, in order to thus achieve a continuous and uninterrupted thermal insulation.

In the present exemplary embodiment, the enveloping unit 206 is formed by a graphite felt. The material graphite is well-suited for the largely hot temperatures and withstands them sufficiently during the ongoing production process. The graphite felt has a very low thermal conductivity and is formed by fibers needled to one another and/or fiber mixtures connected to one another, between which a more or less large air cushion is formed. In the case of graphite felt, a distinction is made between so-called soft graphite felt and hard graphite felt. The hard graphite felt is mostly formed by mixing and pressing fiber mixtures and binding agents, such as phenolic resin, and a subsequent high-temperature treatment. These felts are, most times, cut to the desired dimensions by means of mechanical processing. A deformation to a larger extent is often no longer possible, wherein the shaping is preferably carried out before the binding agent sets.

The soft graphite felt is formed by fibers, mostly cellulose fibers or the like, needled to one other and subjected to a subsequent thermal treatment. Such felts are simple to adjust in regard to their shape, for example by cutting with a knife or a pair of scissors.

The enveloping unit 206 may comprise at least one layer of the hard graphite felt, as needed. However, it would also be possible that the enveloping unit 206 comprises at least one layer of the soft graphite felt. Regardless of this, however, the enveloping unit 206 may also be formed by at least one layer of the hard graphite felt and by at least one layer of the soft graphite felt. This adumbrated is in dashed lines in FIG. 7. In the case of a multi-layer enveloping unit 206, e.g. the at least one layer of a hard graphite felt may be arranged closer to the crucible 201 than the at least one layer of the soft graphite felt. However, it would also be possible that the at least one layer of the hard graphite felt may be arranged closer to the crucible 201 than the at least one layer of the soft graphite felt.

The fibers of the felt may be short fibers and/or long fibers. The short fibers often have a stretched fiber length selected from a value range having a lower limit of 0.01 mm and an upper limit of 1 mm. In the case of so-called long fibers, they have a stretched fiber length selected from a value range having a lower limit of 1 mm and an upper limit of 10 mm.

The crucible 201, for its part, is also formed by a temperature-resistant or high-temperature resistant material. In this regard, the material of the crucible 201 may be selected from a group comprising metal-based, oxide-based, nitride-based, carbon-based, and dense graphite. In this regard, these materials may be, for example, silicon (Si), silicon carbide (SiC), aluminum oxide (Al₂O₃), gallium nitride (GaN), or aluminum nitride (AlN). Ceramic materials may also be used.

In order to hold the enveloping unit 206 in a positioned manner directly on the, in most cases, free-standing crucible 201, a separate holding unit 207 is provided here. As the crucible 201 mostly or preferably has a cylindrical or cylinder-like outer surface, which defines the outer lateral surface 203, the enveloping unit 206 can be easily arranged and fastened after the filling of the accommodation space 202 with the base material meant for the formation of the crystals, or it may be removed from the crucible 201 as needed, after the production of the crystals so they can be removed from the crucible 201, in a simple work step by an operator after releasing the holding unit 207.

For this purpose, the holding unit 207 comprises at least one holding element 208, which is wrapped around the outside of the enveloping unit 206 at least once and thus surrounds the enveloping unit 206 in a circumferential manner. The holding element 208 can also be referred to as holding means or clamping means. To this end, the holding element 208 has a longitudinal extension, which is substantially larger than its cross-sectional dimension. Hence, the holding element 208 is designed to be oblong and largely or preferably non-rigid. Depending on the material used for forming the holding element 208, it may also have a certain inherent stiffness.

Furthermore, the at least one holding element 208 is arranged such that it is arranged so as to contact the outside of the enveloping unit 206. The holding element 208 has a first end section 209 and a second end section 210 spaced apart therefrom in its longitudinal extension. For the mutual connection of the holding element 208 designed to be oblong, it is further provided that the first end section 209 and the second end section 210 are coupled to one another.

If a circumferential prestressing force is applied to the at least one holding element 208 before it is brought into its coupled position of the two end sections 209, 210, a circumferential contacting on the holding unit 207 takes place. This way, a holding force acting on the enveloping unit 206 in the radial direction is applied and the enveloping unit 206 is pressed against the lateral surface 203 of the crucible 201.

The first end section 209 and the second end section 210 of the at least one holding element 208 may be knotted together to form their coupling connection.

For forming the coupling connection of the two end sections 209, 210 of the holding element 208, a separate coupling device 211 could also be provided. This is schematically shown in a simplified manner. The coupling device 211 may for example be structured similarly to what is sufficiently known in the case of tension belts. However, buckle connections or other clamping devices may also be used.

The at least one holding element 208 is also to be formed by a temperature-resistant or a high-temperature resistant material such as a graphite material. The holding element 208 is furthermore to have a sufficient tensile strength as well as a simple transverse deformability. The holding element 208 designed to be oblong and preferably non-rigid may be selected from the group of cord, rope, strip, belt, chain. The formation of the holding element 208 as a strip or a belt is shown in the region of the bottom section 202, and the formation as a cord or a rope is shown in the region of the opening section 205.

Depending on the constructional height of the crucible 201 and a better, complete envelopment of the crucible 201, it is also possible for multiple holding elements 208 to be provided. In this regard, an arrangement spaced apart from one another in the direction of the axial extension of the crucible 201 may be selected.

In order to achieve a circumferential guide of the at least one holding element 208 on the enveloping unit 206, the holding element 207 may comprise at least one guide element 212, wherein it is also possible that multiple of the guide elements 212 per holding element 208 may be arranged distributed across the circumference. For this purpose, the guide element 212 is or the guide elements 212 are arranged, in particular fastened, on that side of the enveloping unit 206 which faces away from the crucible 201. The at least one guide element 212 is formed or configured to guide the at least one holding element 208 in a predefined relative position with respect to the enveloping unit 206.

The enveloping unit 206 may be designed to be plate-shaped, wherein depending on the chosen design, a preformed cross-sectional shape adapted to the outer cross-section of the crucible 201 can also be selected. In most cases or preferably, at least one separating section or overlap section extending in a mainly parallel orientation with respect to the axial extension is provided.

As can now be seen better in FIG. 8, the enveloping unit 206 preferably has a first longitudinal edge section 213 and a second longitudinal edge section 214 when observed in the circumferential direction. In the insulation position of the enveloping unit 206 on the crucible 201, the two longitudinal edge sections 213, 214 may be arranged so as to overlap in the circumferential direction.

Furthermore, the enveloping unit 206 may jut out beyond the crucible 201 in the direction of its axial extension on at least one side facing away from the crucible 201 and thus protrude beyond it.

The device 200 may moreover also comprise a separate housing 215, which defines an accommodation chamber 216 in its interior. The accommodation chamber 216 is preferably sealed from the outer atmosphere and may also be evacuated to an internal pressure that is lower than that of the outer atmosphere. A transparent material may be used as the material for the housing 215. In this regard, this may be a glass material, in particular a quartz glass. The crucible 201 is accommodated in the accommodation chamber 216 along with the enveloping unit 206.

By providing the additional holding unit 207, it is no longer necessarily required that the intermediate space between the outer surface and/or the lateral surface 203 of the crucible 201 and the inner wall surface of the housing 215 is completely filled by the insulating enveloping unit 206. A distanced arrangement is possible.

Furthermore, a heating device 217 is provided to provide thermal energy for heating the crucible 201, its accommodation space 202 and the base material located therein for forming crystals. The heating device 217 is preferably arranged circumferentially around the housing 215 and is further configured to provide the thermal energy required for the crucible 201.

To provide a better overview, the representation of a control device, an energy supply unit and connection and supply lines was refrained from.

FIG. 9 shows a further possible exemplary embodiment of a crucible designed to have multiple parts, which is why for this embodiment, a different reference number is used for the previously described crucible 201, namely the reference number 301. The image shown depicts an axial section in an upright, standing position of the crucible 301.

In the following, only the structure of the crucible 301 will be described, wherein the previously described parts and components for forming the device 200 may also be used in combination with this crucible 301. This is why, in order to avoid unnecessary repetitions, it is pointed to/reference is made to the detailed description in FIGS. 7 and 8 preceding it.

In the exemplary embodiment shown, the crucible 301 comprises a crucible bottom part 302, at least one crucible wall part 302 and a crucible cover part 304. In order to be able to orient the individual components forming the crucible 301 so as to be positioned relative to one another, at least one positioning assembly 304 is provided or formed in this exemplary embodiment. In this case, the positioning assembly 304 is arranged or formed between the crucible bottom part 302, namely a wall section rising up from the bottom, and the at least one crucible wall part 303.

The positioning assembly 304 may be designed in a variety of ways, wherein at least one positioning element each is provided on ends of the crucible bottom part 302 and of the crucible wall part 303, which ends face one another. The positioning elements facing one another are formed or configured to mutually cooperate. The positioning assembly 304 may be designed, for example in the form or type of a tongue and groove joint, projecting and recessed positioning elements or the like.

FIG. 10 shows a further exemplary embodiment of a multi-part crucible 601. The crucible 601 comprises a guide surface 603 running towards the seed crystal layer 602 and inclined against an axis of an accommodation space, wherein the shortest distance from the guide surface 603 to the axis of the accommodation space 604 decreases from a lower edge of the guide surface 603 facing the crucible bottom part 605 towards an upper edge of the guide surface 603 facing the cover 606 of the crucible 601. It is particularly preferred for the guide surface 603 to be designed conically.

The guide surface 603 may be part of an insert 607 inserted into the crucible 601. The insert 607 and/or the crucible bottom part 605 and/or the crucible wall part 608 and/or the crucible cover part 606 may each be made of ceramics, of metal, or a mineral material, in particular of fireproof material, carbides, oxides, or nitrides.

The insert 607 may comprise a holding projection 609 protruding from the guide surface 603 in the radial direction and facing away from the axis a of the accommodation space 604.

The holding projection 609 may be designed to be circumferential around the guide surface 603 in the circumferential direction. Moreover, the holding projection 609 may be arranged in sections or entirely between the crucible bottom part 605 and the crucible wall part 609 and be fixed by these two components. Alternatively, however, the holding projection 609 may also be arranged between two sections of the crucible wall part 609 if it is structured having multiple parts.

In this regard, the crucible bottom part 605 may be designed to be pot-shaped and the crucible wall part 608 may be designed to be tubular. The crucible bottom part and the crucible wall part may be arranged on top of one another so as to be aligned with one another.

As can be seen in FIG. 10, a pyrometer 610 for detecting a temperature of the crucible 601 or in the crucible 601 may be provided.

The crucible cover part 606 may have an opening 611, through which a temperature in the accommodation space or on a side of the seed crystal layer 602 facing away from the accommodation space can be detected by means of the pyrometer 610.

According to FIG. 11, the seed crystal layer 507 is assembled from multiple seed crystal plates 507a, 507b, 507c in a tessellated manner. In this regard, the individual seed crystal plates 507a, 507b, 507c are preferably assembled such that the crystal orientations of the seed crystal plates 507a, 507b, 507c are oriented uniformly and a closed flat surface is formed. It has proven favorable in this regard that the individual seed crystal plates are made from wafers.

At least one epitaxy layer of monocrystalline silicon carbide may be applied to the seed crystal plates 507a, 507b, 507c, in particular by means of a CVD method. The application of the epitaxy layer, in addition to the arrangement and connection of the individual seed crystal plates 507a, 507b, 507c on a substrate, constitutes a possibility to connect the individual seed crystal plates 507a, 507b, 507c to one another. The assembled seed crystal layer 507 may be subjected to a heat treatment to eliminate any possible defects. This way, the seed crystal layer 507 may be heated, for example, to a temperature of more than 1200° C., and this temperature may be maintained between 10 min and 3 h. Afterwards, a cooling and thermal annealing of defects may take place at a temperature of less than 800° C. The heat treatment may take place in an inert gas atmosphere, for example.

As can further be seen in FIG. 11, the seed crystal plates 507a, 507b, 507c may each have a polygonal, in particular hexagonal, circumferential contour.

The seed crystal plates 507a, 507b, 507c may be connected to the cover 404 of the crucible 403 with or without intermediate layers arranged between the seed crystal plates and the cover, as is shown for example in FIG. 1. However, the seed crystal plates 507a, 507b, 507c may also be applied to a substrate separate from the cover 403, as is shown in FIG. 6.

The seed crystal layer 507 has a preferred thickness of 350-2000 μm and a preferred mass per unit area of between 2.20 kg/m² and 3.90 kg/m².

Moreover, the seed crystal layer 507 may have one or two polished and/or lapped surfaces. It has proven particularly favorable that the seed crystal layer has an area-related roughness value of between 10 nm and 0.5 nm. The area-related roughness value is defined, for example, in the EN ISO 25178 standard.

According to FIG. 12, the device 501 according to the invention for growing single crystals, in particular single crystals of silicon carbide, comprises a crucible 502. The crucible 502 defines an outer lateral surface 503 and moreover delimits an accommodation space 504 with an axial extension between a bottom section 505 and an opening section 506. The accommodation space 504 is designed for growing the crystals, wherein at least one seed crystal layer 507 is arranged in the opening section 506. The crucible 502 may be arranged in a chamber equivalent to the chamber 402 and also be heated inductively.

Contrary to the embodiment according to FIG. 1, the seed crystal layer 507 is weighted down by means of a weighting mass 508 on a side facing away from the accommodation space 504 and is fixed in its position against at least one holding section 509 arranged in the opening section by means of the weight force of the weighting mass 508. It is preferably provided that the seed crystal layer 507 is locked into position only by means of the weight force of the weighting mass 508. Apart from this, the device 501 may be designed like the furnace of FIG. 2.

As can further be seen in FIG. 12, the seed crystal layer 507 may contact the at least one holding section 509 with at least an outer edge region.

The holding section 509 may be designed to extend circumferentially around an opening 510 of the opening section 506.

According to FIGS. 13 and 14, the holding section 509 may be formed at least by a section of the mount 510 having an annular or tubular base body 511, the section facing a longitudinal central axis of the crucible, wherein the holding section 509 protrudes from the base body 511. The mount 510 may be screwed into the crucible 502 as is shown in FIG. 12, or inserted as is shown in FIG. 13.

According to the embodiment shown in FIG. 13, the mount 510 may have an external thread 512 on a lateral surface of the base body 511, wherein a lateral surface delimiting the opening may have an internal thread 513 corresponding to the external thread.

According to FIG. 14, the mount 510 inserted into the crucible may be supported on a projection 514 of the crucible 502. The projection 514 may be designed, for example, to extend circumferentially around the opening of the opening section 506.

The weighting mass 508 may be arranged between the seed crystal layer 507 and a cover 515 of the crucible 502, wherein the weighting mass 508 and the cover 515 are formed separately from one another. The weighting mass 508 is preferably arranged loosely between the cover 515 and the seed crystal layer 507.

The seed crystal layer 507 may be designed as a mechanically self-supporting layer or also be applied to a carrier substrate 516, as it is shown in FIG. 15. If the seed crystal layer 507 is applied to a carrier substrate, the weighting mass 508 may rest on the carrier substrate 516. Graphite has proven particularly suited for being the carrier substrate.

The weighting mass 508 and/or the mount 510 may be made of metal, ceramics, mineral or plastics. Fireproof materials, carbides, oxides, or nitrides, for example, have proven particularly suitable.

Finally, as a matter of form, it should be noted that for ease of understanding of the structure, elements are partially not depicted to scale and/or are enlarged and/or are reduced in size.

List of reference numbers

| | |
|---|---|
| 200 | Device |
| 201 | Crucible |
| 202 | Receiving space |
| 203 | Lateral surface |
| 204 | Bottom section |
| 205 | Opening section |
| 206 | Enveloping unit |
| 207 | Holding unit |
| 208 | Holding element |
| 209 | First end section |
| 210 | Second end section |
| 211 | Coupling device |
| 212 | Guide element |
| 213 | Longitudinal edge section |
| 214 | Longitudinal edge section |
| 215 | Housing |
| 216 | Accommodation chamber |
| 217 | Heating device |
| 301 | Crucible |
| 302 | Crucible bottom part |
| 303 | Crucible wall part |
| 304 | Crucible cover part |
| 305 | Positioning assembly |
| 401 | Furnace |
| 402 | Chamber |
| 403 | Crucible |
| 404 | Cover |
| 405 | Seed crystal |
| 406 | Bottom section |
| 407 | Base material |
| 408 | Heater |
| 409 | Insulation |
| 410 | Lumps |
| 411 | Powder |
| 412 | Height |
| 413 | Pellet |
| 414 | Silicon |
| 415 | Axis |
| 416 | Bearing |
| 417 | Storage container |
| 418 | Feed line |
| 501 | Device |
| 502 | Crucible |
| 503 | Lateral surface |
| 504 | Accommodation space |
| 505 | Bottom section |
| 506 | Opening section |
| 507 | Seed crystal |
| 507a-c | Seed crystal plates |
| 508 | Weighting mass |
| 509 | Holding section |
| 510 | Mount |
| 511 | Base body |
| 512 | External thread |
| 513 | Internal thread |
| 514 | Projection |
| 515 | Cover |
| 601 | Crucible |
| 602 | Seed crystal layer |
| 603 | Guide surface |
| 604 | Accommodation space |
| 605 | Crucible bottom part |
| 606 | Crucible cover part |
| 607 | Insert |
| 608 | Crucible wall part |
| 609 | Holding projection |
| 610 | Pyrometer |
| 611 | Opening |

1. A device for growing single crystals, in particular single crystals of silicon carbide, comprising a crucible (601), which crucible (601) defines an outer lateral surface and moreover delimits an accommodation space (604) with an axial extension between a bottom section and an opening section, wherein the accommodation space (604) is designed for growing the crystals, wherein the device hast at least one seed crystal layer (602), wherein the crucible (601) is arranged in a chamber, in particular made of a glass material, for example quartz glass, wherein an induction heater is arranged around the chamber, wherein the crucible (601) is designed to have multiple parts and comprises a crucible bottom section (302, 605), at least one crucible wall part (608), and a crucible cover part (303, 606), which are releasably connected to one another.

2. The device according to claim 1, wherein a positioning assembly (304) is provided, by means of which positioning assembly (304) at least the crucible bottom part (302) and the at least one crucible wall part (303) are positioned on the ends facing one another oriented in a predefined position relative to one another.

3. The device according to claim 1, further comprising a guide surface running towards the seed crystal layer (602) and inclined against an axis of the accommodation space, wherein the shortest distance from the guide surface to the axis of the accommodation space decreases from a lower edge of the guide surface facing the bottom section towards an upper edge of the guide surface facing a cover of the crucible.

4. The device according to claim 3, wherein the guide surface is conically designed.

5. The device according to claim 3, wherein the guide surface is part of an insert inserted into the crucible, wherein the insert and/or the crucible bottom part and/or the crucible wall part and/or the crucible cover part is preferably made of ceramics, of metal, or a mineral material, in particular of fireproof material, carbides, oxides, or nitrides.

6. The device according to claim 5, wherein the insert has a holding projection protruding from the guide surface in the radial direction and facing a side wall of the accommodation space.

7. The device according to claim 6, wherein the holding projection is designed to extend circumferentially around the guide surface in the circumferential direction.

8. The device according to claim 6, wherein the holding projection is arranged, at least in sections, between the crucible bottom part and the crucible wall part or between two sections of the crucible wall part.

9. The device according to claim 1, wherein the crucible bottom part is designed to be pot-shaped, and the crucible wall part is designed to be tubular, wherein the crucible bottom part and the crucible wall part are arranged on top of one another.

10. The device according to claim 1, further comprising a pyrometer for detecting at least a temperature of the crucible or in the crucible.

11. The device according to claim 10, wherein the crucible cover part has an opening, wherein the device is configured to detect, through said opening, a temperature in the accommodation space or on a side of the seed crystal layer facing away from the accommodation space by means of the pyrometer.
